(19) United States
(12) Patent Application Publication
(10) Pub. No.: US 2020/0006273 A1
(43) Pub. Date: Jan. 2, 2020

(54) MICROELECTRONIC DEVICE INTERCONNECT STRUCTURE

(71) Applicant: Intel Corporation, Santa Clara, CA (US)

(72) Inventors: Manish Dubey, Chandler, AZ (US); Kousik Ganesan, Chandler, AZ (US); Suddhasattwa Nad, Chandler, AZ (US); Thomas Heaton, Mesa, AZ (US); Sri Chaitra Jyotsna Chavali, Chandler, AZ (US); Amruthavalli Pallavi Alur, Tempe, AZ (US)

(21) Appl. No.: 16/022,453

(22) Filed: Jun. 28, 2018

(51) Int. Cl. H01L 23/00; H01L 23/498; H01L 21/48

(52) U.S. Cl. CPC H01L 24/17; H01L 24/16; H01L 24/24; H01L 23/49833; H01L 21/4846; H01L 2224/81815; H01L 2224/1703; H01L 2224/24155; H01L 24/81; H01L 2224/81203; H01L 2224/81385; H01L 2224/16238

(57) ABSTRACT

A microelectronic device is formed including two or more structures physically and electrically engaged with one another through coupling of conductive features on the two structures. The conductive features may be configured to be tolerant of bump thickness variation in either of the structures. Such bump thickness variation tolerance can result from a contact structure on a first structure including a protrusion configured to extend in the direction of the second structure and to engage a deformable material on that second structure.

### TECHNICAL FIELD

Embodiments described herein relate generally to methods and apparatus for forming microelectronic devices and components thereof, and more particularly relate to the configuration and use of structures configured to be adaptable for dimensional variations in one or more interconnect structures being mechanically and electrically coupled to one another to form a microelectronic device.

### BACKGROUND

Many forms of microelectronic devices, such as IC (integrated circuit) packages, include a substrate supporting one or more devices (referred to herein as “die”), retained on one or more surfaces of the substrate, and may include one or more “embedded die” retained at least partially beneath a surface of a substrate structure. Additionally, some microelectronic devices include additional components to the die and substrate, wherein the additional components interconnect with the one or more die, the substrate and/or other of such components to form at least a portion of the microelectronic device. Examples of such “other” components include, for example, interposers, redistribution layers, modular substrate components, and other structures forming one part of an electrically/mechanically interconnected structure. For purposes of the present disclosure, the term “interconnect structure” is used to refer generically to structures of a microelectronic device which are physically and electrically engaged with one another to form some portion of a microelectronic device; such as, for example, the attachment of any two or more of any of: a die, a substrate, an interposer, a redistribution layer, etc. Similarly, the term “interconnect contact” is used herein to refer to the structures on each interconnect structure configured to establish the individual physical and electrical connections; and thus such term is used herein to generically refer to any of multiple structures for such purpose, including contact pads (which may be essentially planar, or in the form of contact pillars), solder bumps (whether solder balls or another form), conductive adhesive, etc.

As microelectronic devices advance, establishing reliable physical and electrical connections between such interconnect structures becomes increasingly difficult. For example, ideally, engaging surfaces of such interconnect contacts of each interconnect structure (i.e. those surfaces that will at least initially engage one a complementary surface of another structure) would lie in a single plane, to facilitate simultaneous and uniform contact as the interconnect structures are placed in engagement with one another. This ideal situation, however, rarely exists in the real world. Deviations from planarity can occur in any interconnect structure as a result of imperfections or other variations in the interconnect structure.

Additionally, some structures, such as those used as substrates or interposers, for example, can warp or otherwise develop deviations from ideal planarity under processing conditions, particularly as dimensions get larger as a result of integration of increased numbers of components. Variations in the pitch or size of conductive structures in an interconnect structure can also result in localized variations of the engaging surfaces relative to an ideal plane. And formation of the interconnect contacts themselves may be subject to variation. As just one example, forming solder bumps of a uniform size (within, for example, 1 μm to 2 μm variation) can be difficult, but can be further complicated when the solder bumps are formed on contact pads of different horizontal (lateral) dimensions. In that situation, it may be difficult to form solder bumps of the same vertical dimension on smaller, more narrowly pitched contact pads, compared to those formed on larger, more widely pitched contact pads. As a result of these multiple different potential mechanisms causing non-uniformity in interconnect structures, process windows for forming the interconnect structures, the interconnect contacts, and for the interconnecting process itself have to be controlled within relatively restrictive parameters in order to achieve satisfactory yield of the microelectronic devices being formed.

### BRIEF DESCRIPTION OF THE DRAWINGS

FIGS. 1A-1B depict simplified cross-sectional representations of example variations between interconnect structures as may be experienced with conventional microelectronic devices; wherein FIG. 1A depicts example cross-sectional representations of opposing interconnect structures at three horizontally offset locations prior to interconnecting of the structures; and wherein FIG. 1B depicts the opposing interconnect structures after interconnecting of the structures.

FIGS. 2A-2B depict simplified cross sectional representations of interconnect structures in which one interconnect structure includes interconnect contacts having respective protrusions in accordance with the description herein; in which FIG. 2A depicts the opposing interconnect structures prior to interconnection; and in which FIG. 2B depicts the opposing interconnect structures after initial engagement between the opposing interconnect structures.

FIGS. 3A-3B depict simplified cross-sectional representations of example alternative configurations of protrusions on representative interconnect contacts; in which FIG. 3A depicts three alternative configurations for protrusions prior to engagement between the two interconnect structures; in which FIG. 3B depicts the interconnect structures after initial engagement between the opposing interconnect structures.

FIGS. 4A-4C depict a simplified cross-sectional representation of an interconnect contact during sequential representative stages of forming a protrusions such as those depicted in FIGS. 2A-2B and 3A-3B.

FIGS. 5A-5C depicts a representative portion of an example microelectronic device configuration, wherein in FIG. 5A the interconnect contacts including protrusions are implemented in connections between an interposer and a substrate assembly; and wherein FIG. 5B depicts an example configuration for forming a structure such as that of FIG. 5A through strip processing; and wherein FIG. 5C depicts an alternative configuration for forming a structure such as that of FIG. 5A through strip processing.

FIG. 6 depicts an example method for forming a microelectronic device through use of the techniques and structures described herein.

FIG. 7 depicts a system level diagram of an electronic system which may incorporate an embedded die microelectronic device such as any of the microelectronic devices as described herein.

### DESCRIPTION OF EMBODIMENTS

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims.

The present description addresses example interconnect structures of microelectronic devices which will be physically and electrically engaged with one another through coupling of conductive features on the two structures. Such coupling can be achieved in such as through use of one or more forms of deformable material, such as, for example, various forms and formulations of solder, conductive adhesive materials, etc. An example environment in which the described interconnect contact configurations are of particular benefit is where devices are interconnected through use of thermal compression bonding, in which two components are placed under pressure to establish engagement with one another, and a deformable material is redistributed, such as, for example, reflowing solder, to establish physical and electrical engagement between complementary contacts of two or more connecting structures.

As microelectronic device development progresses, individual die and interconnect structures (and their features) progressively shrink, requiring increasingly tighter control over increasingly smaller structures. As a result, the height variation between different contact structures on an interconnect structure (generally referred to as “bump thickness variation” or “BTV”), is a continuing challenge.

Examples described herein include the forming of contact structures on a first interconnect structure, the contact structures including one or more protrusions extending in the direction of a second interconnect structure. In the described examples, the protrusions are configured to engage a deformable element (in some examples, a solder bump) on the second interconnect structure, to allow individual connections to individually adapt to localized BTV variations on one or both of the interconnect structures.

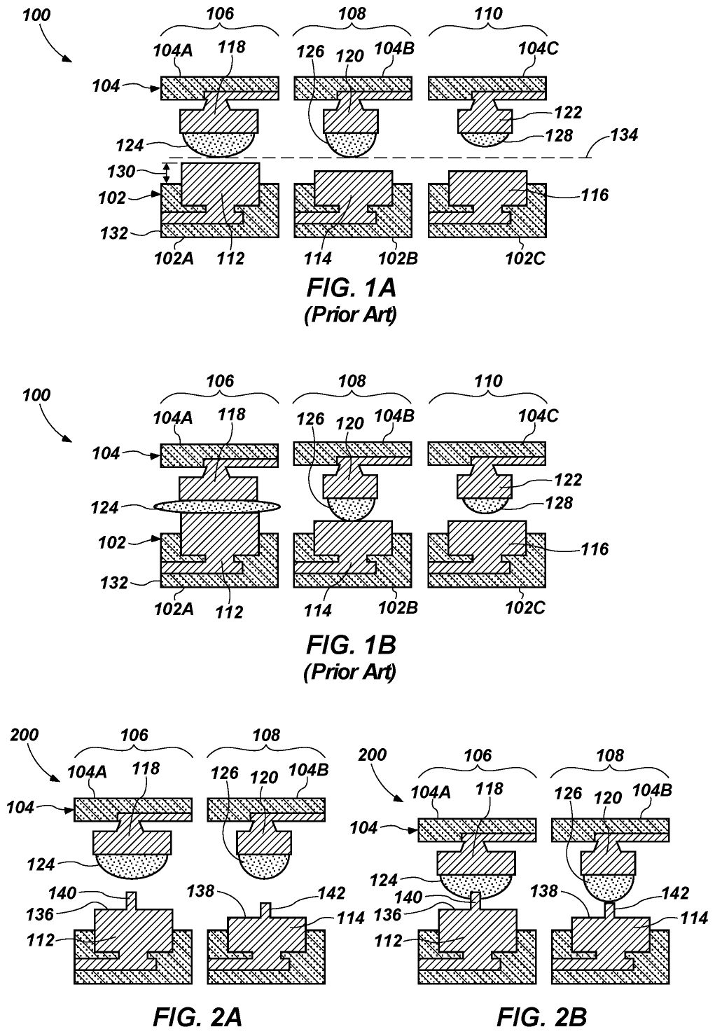

Referring now to FIGS. 1A-1B, the figure depicts simplified cross-sectional representations of an example conventional microelectronic device structure 100, including two interconnect structures 102, 104, of which representative regions 102A-102C, and 104A-104C are shown at three horizontally offset regions 106, 108, and 110.

The example interconnect structures 102, 104 are representative of various structures which may be interconnected to form a microelectronic device 100. For example, the indicated structures may be the first level interconnect between a semiconductor die and a supporting structure. In such example, interconnect structure 104 may be seen as representative of the semiconductor die, with interconnect structure 102 being representative of a package substrate, a supporting interposer, or a redistribution layer formed on another structure.

For clarity and streamlining of the present description, except as expressly noted, the examples and explanation of the interconnect structure will be described in the context of a microelectronic device “substrate” having a first level interconnect (FLI) side facilitating electrical connection to one or more die and a second level interconnect (SLI) side facilitating electrical connection to an external structure, such as a motherboard, printed circuit board, or other structure external to the microelectronic device. However, unless expressly identified otherwise herein, the described structure, relationships and processes are directly applicable to other forms of interconnect structures and their interconnections as discussed earlier herein.

Each region 106, 108, 110 includes a respective contact pad 112, 114, 116 on the lower interconnect structure 102; and a respective contact pad 118, 120, 122 on the upper interconnect structure 104A (for example, in a first level interconnect environment, a semiconductor die). As can be seen from a comparison of regions 106, 108, and 110, the contact pads 120, 122 of regions 108 and 110 are of a reduced horizontal dimension, relative to contact pad 118 of region 106. While each contact pad 118, 120, 122 includes a respective solder bump formed thereon, as indicated at 124, 126, and 128, due to the reduced horizontal dimension of contact pads 120 and 122, in many processing environments it can be difficult to form solder bumps of the same vertical dimension on narrower contact pads as on wider contact pads. Additionally, as indicated by the difference in dimension between solder bumps 126 and 128 in regions 108 and 110, variations may result from conditions other than the dimensions of the underlying contact pad.

Additionally, in some examples, BTV can occur between structures in one location versus another. For example, as can be seen in region 106, the height 130 of contact pad 112 above the surrounding structure 132, is greater than the corresponding height of either of contact pads 114, 116 relative to the surrounding structure 132. Such height differences may occur, for example, as a result of deposition or plating operations that proceed at different rates depending on one or more of: the structure being formed, the proximity to other features, process variations, etc. The result is that even if each solder bump 124, 126 and 128 on interconnect structure 104 extended to a common plane, exhibiting no BTV, dimensional variations on the other interconnect structure 102 can present a challenge to physically and electrically interconnecting the two interconnect structures.

As noted previously, in an optimal situation, the contact pads 112, 114, 116 on lower interconnect structure 102 would lie in a common plane, and the lowermost engagement surface of each solder bump 124, 126, and 128 would also ideally extend to a respective common plane so that each solder bump 124, 126, and 128 and the respective contact pads 112, 114, 116 could be brought into contact with one another essentially simultaneously. A reference line 134 identifies one example of an idealized line of planarity to which the lowermost engagement surface of each solder bump would extend. In this example, reference line 134 corresponds to the vertical dimension of solder bump 126 in region 108, though other idealized lines could be drawn.

Referring now to FIG. 1B, the figure depicts the structure of FIG. 1A when the lower and upper interconnect structures 102, 104, respectively, are bonded together, such as through thermal compression bonding. In such thermal compression bonding, the interconnect structures are brought into engagement with one another under conditions of heating and pressure sufficient to establish contact between the contact structures on the two interconnect structures. Once the interconnect structures are in initial contact, a selected degree of additional pressure (termed “chase”) is applied in an effort to assure that each solder bump (regardless of vertical dimension) makes contact with the opposing contact structure. In some examples, the chase may be customized based on an identified BTV in one or more of the interconnect structures.

Generally, the chase will be selected with the objective of bringing together all opposing contact structures to be coupled to one another. However, due to potential variations in interconnect structures (for example, of one or both of a substrate and die), and resulting BTV, the chase must be selected in view of competing concerns.

For example in one failure mode, as depicted in FIG. 1B, application of the selected chase has caused bulging of the solder bump in region 106 going outside the dimensions of the contact pads 112, 118, and thus presenting a risk of solder bridging (“solder bump bridging”), with adjacent contact structures resulting in electrical shorts. This risk is magnified if similar bulging occurs at an adjacent contact structure. At the same time, in view of the degree of BTV, the applied chase was insufficient to cause contact and bonding in region 110, resulting in a non-contact defect. As a result, with the BTV as reflected at the three regions 106, 108, 110 in this simplified example, there was not a sufficient process window to establish a satisfactory interconnection in all three regions. For current packaging configurations, BTV needs to be controlled within a few μm, for example no more than 8 μm to 12 μm for many microelectronic devices; and for some current packaging configurations BTVs of 8 μm to 10 μm can be outside of a manageable process window.

Referring now to FIGS. 2A-2B, the figures depict simplified representations of a microelectronic device 200 including contact structures analogous to the structures of FIGS. 1A-1B (specifically that of regions 106 and 108 of each figure), but in which the lower contact structures have been constructed to include not only a contact pad 112, 114, but a protrusion 140, 142 extending outwardly from the surface of the contact pad 112, 114. For clarity of explanation, structures that correspond directly with structures of FIGS. 1A-1B have been numbered similarly. In the depicted example, each of contact pads 112, 114 includes a generally planar surface, 136, 138, respectively, from which respective protrusions 140, 142 extend. Such a planar surface is not required for contact pads 112, 114, or for the definition of a protrusion extending therefrom, though such a planar surface is a desirable configuration from a manufacturing perspective.

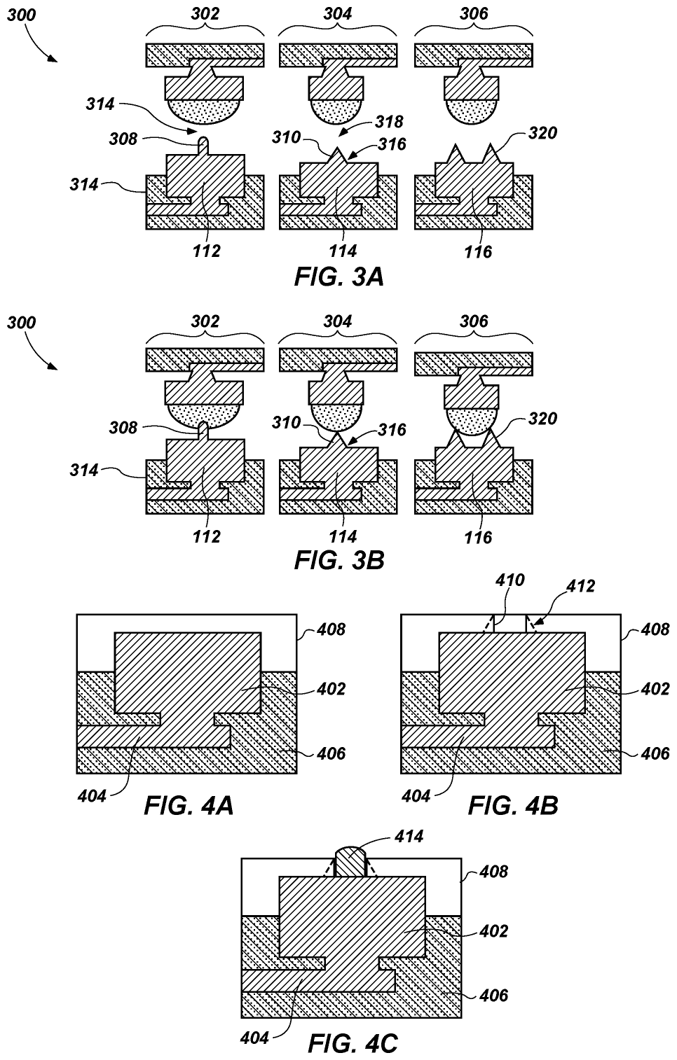

As will be discussed in more detail relative to FIGS. 4A-4D, protrusions 140, 142 may be formed by any of a variety of processes. In many examples, the protrusions will be defined at least in part through photolithography. In the simplest embodiments, the protrusions may be defined essentially as columns or pillars, of any desired horizontal cross-section (i.e., round, rectangular, square, or more complex shapes) along the height of the protrusion. The primary function of the protrusion is to extend to penetrate an opposing solder bump (or other deformable material) in regions where the contours of the upper and lower interconnect structures result in a closer spacing than that found in other regions, as depicted in FIG. 2B. As a result, as discussed in more detail relative to FIGS. 3A-3B, the protrusions may be formed with a profile to promote that function.

The specific dimensions of the protrusions can be selected relative to the specific application in question, and the dimensions of the interconnect structures thereof. As a result, for many current technology node applications the protrusions may have a vertical dimension within the range of 3 μm to 14 μm, with vertical dimensions between 4 μm and 8 μm being desirable for many applications.

Generally speaking, the greater the vertical dimension of the protrusion, the wider the process window for completing the interconnection. However, the protrusions should be limited in vertical dimension so as to stay within the minimum expected dimension of the solder bump (or other deformable material), so under bonding conditions (such as thermal compression bonding), the protrusion does not extend through the solder bump to contact the underlying contact pad.

As a result, the protrusions, when formed generally as a pillar, with a uniform horizontal cross-section, may have a horizontal cross-sectional dimension between 3 μm and 8 μm. The protrusions can bridge the larger gaps between contact structures to be coupled to one another, and facilitate “wetting” of the solder sufficient for the solder (or other deformable material) to reflow between opposing contact structures and establish the physical and electrical connections. Thus inclusion of the protrusions facilitates accommodating a greater range of BTV on either or both interconnect structures. This enables a wider process window for thermal compression bonding, for example, allowing use of structures with relatively increased BTV, and/or reducing the chase required to achieve physical contact at all locations sufficient to assure adequate bonding.

In some examples, the lateral dimension of the protrusions may be selected in reference to either the lateral dimension of the contact pad on which the protrusion is located, or the intended lateral dimension of the solder bump that the protrusion is to engage. For example, the protrusion might have a maximum lateral dimension selected to be no more than 30% of the maximum lateral dimension of the solder bump it will engage; or in other examples, no more than 30% of the maximum lateral dimension of the contact pad on which it is located.

Referring now to FIGS. 3A-3B, the simplified representations include a representative regions 302, 304, 306 of a microelectronic device 300 in which lower interconnect structure 314 depicts examples of different forms of protrusions 308, 310, 312 (depicted as alternatives on the corresponding structures for brevity, but in many examples all protrusions on an interconnect structure may be formed with comparable shapes and sizes). Region 302 includes a protrusion 308 of a generally pillar configuration, but having a tapering dimension toward the distal end, indicated generally at 314.

As depicted in region 304, another example configuration of protrusion 310 does not include a portion with a uniform horizontal cross-section, but includes a wider proximal or base portion, indicated generally at 316, and a taper toward a distal portion, indicated generally at 318. The term “taper” is used herein to identify a structure having profile with a declining dimension in a given direction. Such a declining dimension (“taper”) may be a generally linear translation, such as would result in a generally conical structure, or may be generally radiused, providing a more rounded structure (at least in the radiused portion). As will be apparent to persons skilled in the art having the benefit of this disclosure, limitations of semiconductor manufacturing will not result in protrusions formed with geometrical precision as to a linear taper or a radius, and will thus not result in an idealized form as used in the figures for discussion purposes. Thus, the above descriptions refer to the general trend shape of the protrusion in a given region, and not to a mathematically defined shape. Thus, the term “generally tapered” refers to a generalized profile of a protrusion, or portion thereof, subject to manufacturing capabilities. The generally conical protrusion 310 may be found to offer improved resistance to damage during bonding processes, due to the (potentially) lower height to width ratio.

As depicted in region 306, multiple protrusions 320 may be formed on a single contact pad. The use of multiple protrusions can improve the reflow of solder during the bonding process. Additionally, multiple protrusions may be spaced relative to one another to reduce the criticality of alignment of the two interconnect structures in an X-Y plane. For example, an array of three or four protrusions might be arranged to compensate for misalignment between interconnect structures in either an X or Y direction. Though multiple protrusions 320 are depicted in the example of FIG. 3A-3B as having a generally conical profile, other configurations as described herein, including simple pillars, may be used.

Referring now to FIGS. 4A-4C, the figures depict a simplified cross-sectional representation of an interconnect contact during sequential representative stages of forming protrusions such as those depicted in FIGS. 2A-2B and 3A-3B. FIG. 4A depicts a representative portion of a lower interconnect structure 400 having a substrate portion 406, with a conductive pad 402 formed thereon, and with a conductive trace 404 extending to the conductive pad 402. A layer of photoresist film 408 has been formed over conductive pad 402 to facilitate forming of a protrusion. As known to persons skilled in the art, the photoresist film may be formed such as by laminating or by spin coating the photoresist film over the underlying substrate 406. In some examples, the photoresist film 408 may include multiple vertically adjacent layers, for example, multiple layers of different dry film resist elements.

Referring now to FIG. 4B, the figure depicts the structure after patterning of the photoresist. In a relatively simpler embodiment, in which the protrusion will have an essentially uniform horizontal cross-section along its height, the patterning may include defining essentially vertical sidewalls, as indicated at 410. Additionally, as discussed below such patterning may be used in combination with selected deposition techniques to produce a protrusion with a varying horizontal cross-section along its height.

Alternatively, protrusions having a tapering dimension in the distal direction may be formed in part lithographically. In order to form such structures, the photoresist film 408 may be patterned in a manner to result in an aperture, defined by sidewalls indicated generally at 412, that narrows toward the top of the photoresist film 408. Such an aperture may be formed, for example through incremental variations in the photoresist exposure and/or developer process, including, for example, curing of the mask through impact with angled radiation. As other alternatives, the photoresist film may be formed in multiple stages to facilitate defining the desired narrowing aperture. In some examples, the photoresist film 408 may include multiple vertically adjacent layers, for example different dry film resist elements, which may be of different properties or characteristics to facilitate defining a tapering region for the protrusion. Once a tapered mask region is formed, metallic protrusions may be formed within the mask aperture, as described below.

The protrusions may be formed through any of several different manufacturing techniques. A first example technique is through electrodeposition, which may be of different types. Electrodeposition techniques may be implemented to achieve selective growth of the protrusions within an area defined by a photomask. Such electrodeposition techniques for depositing copper will typically include an electrolytic copper plating bath which include sulfuric acid, chloride ions, cupric ions (supplied typically from copper sulfate or copper oxide powders) as well as one or more additional compounds with organic additives as rate controlling agents, commonly identified in the literature as either an accelerator, suppressor, or a leveler. A first example technique is through reverse current electrodeposition (also known as reverse pulse plating or “RPP”) of a metal protrusion. For purposes of the present description, the electrodeposition has been described for copper (Cu), but other metals may be formed electrodeposited in an analogous manner, including, by way of example only, nickel, cobalt, iron, gold, silver, tin, palladium, etc.

As one example process, the substrate may be placed in an electrolyte bath comprising, for example, sulfuric acid, hydrochloric acid, and Cu²⁺ ions generated from copper sulfate or copper oxide, with one or more organic compounds as rate controlling agents. Such organic compounds can include one or more compounds that function to suppress the deposition rate of copper metal in certain portions of the substrate while increasing the deposition rate of the copper metal in other portions of the substrate. For example, certain rate-controlling additives that may be used to suppress the copper deposition rate, include, for example: polyethers such as polyethylene glycol (PEG). polypropylene glycol (PPG), nitrogen bearing heterocyclic or non-heterocyclic aromatic compounds, large molecular weight polyoxy-alkyl type compounds. In contrast, rate controlling additives that may be used primarily to increase the copper deposition rate (such as within high-aspect features include, by way of example only, sulfur-based organic molecules such as bis (sodiumsulfopropyl) disulfide (“SPS”), other disulfides, and surfactants. By controlling the ratio of forward and reverse electrolytic currents and their durations, and varying the ratio during forming of the protrusion, a protrusion having at least a portion generally narrowing to form a generally conical profile structure may be generated.

Alternatively, the protrusion may be formed through direct-current (DC) electrodeposition of copper. In this method, an electrolyte bath generally as described relative to reverse current electrodeposition is used. By balancing the ratio of inorganic and organic additives in the electrolytic bath, the bottom up fill nature of the additives may be used to provide a tapering profile to the formed protrusion.

In other examples, the protrusions may be formed by other recognized deposition methods, such as sputtering, plasma vapor deposition (PVD), chemical vapor deposition (CVD), etc. Utilizing such deposition processes, the material for the protrusion may either be sputtered over the contact pads, and potentially other surfaces, followed by photolithographically masking and etching to define the protrusions. Alternatively, masks may be utilized to define the protrusion region, as discussed above, and material for the protrusion may be sputtered over the mask, and then subsequently polished to expose the mask; and then the mask removed to leave the protrusions.

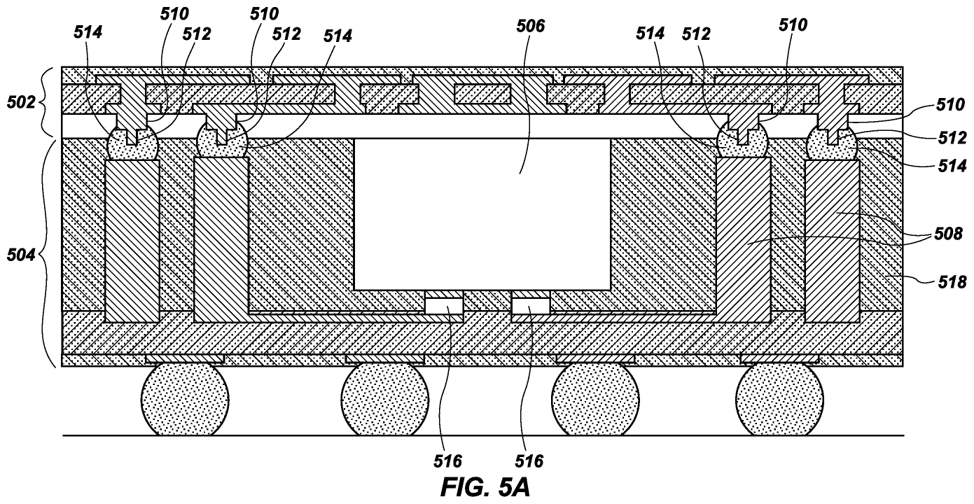

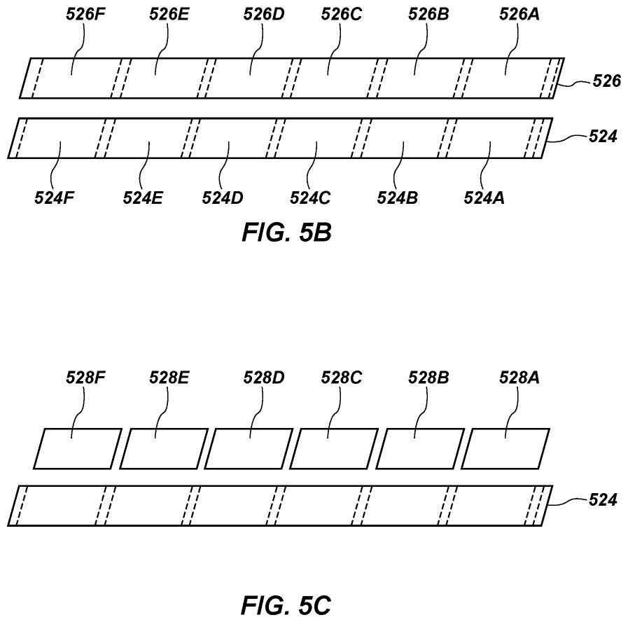

As noted previously herein, forming of protrusions can be used to improve the process window for interconnecting various structures within a microelectronic device beyond the discussed example of a first level interconnect between a semiconductor die and a substrate. Referring now to FIGS. 5A-5C, FIG. 5A depicts an example microelectronic device 500 utilizing protrusions as described above in forming a mid-level interconnect connecting an interposer 502 to a substrate 504 on opposite sides of a semiconductor die 506. In the depicted example, pillars 508, such as copper pillars, are formed on the substrate and extend through a dielectric 518 around die 506. Pillars 508 form conductive paths known as through silicon vias (“TSVs”) (though such terminology is used without implying that the pillars are actually extending through silicon), extending vertically alongside die 506. In the depicted example, the contact pads 510 on the interposer include protrusions 512 extending to engage solder bumps 514 formed on respective pillars 508.

The depicted environment is one in which there are several areas for potential variations in BTV. For example, variations can result in the fill surrounding the semiconductor die 506 due to differences in the dimensions of first level interconnect contacts, indicated generally at 516, and/or die 506. Alternatively, manufacturing processes can result in variability in the thickness of the interposer resulting in unintended variations in the chase applied during a thermal compression bonding operation. As a result, the use of the described protrusions to engage the deformable material on the mating interconnect structure can provide an increased process window for the assembly of the described interconnect structures. An increased process window provides an additional advantage in easing manufacturing constraints in assembling such devices through strip processing.

Referring again to FIGS. 5B-5C, the figures depict example implementations of strip processing to assemble structures such as the microelectronic device 500 of FIG. 5A. In some examples of strip processing, both interconnect structures may be assembled from portions of respective wafers (known as “strips”) 524, 526 with each portion (strip) containing multiple sites of the respective interconnect structures (524A-F, 526A-F). For example, in the example structure of microelectronic device 500 of FIG. 5A, the substrate strip 524 would include, at each device site 524A-F, a substrate 504, in the example of FIG. 5A, including a semiconductor die 506, encapsulated within a dielectric, with the formed pillars 508 supporting solder bumps 514. Similarly, the interposer strip would include the multiple interposer sites 526A-F, with each site having an interposer 504 including multiple contact pads 510 having protrusions 512 formed thereon. In an alternative form of strip processing, as depicted in FIG. 5C, only one interconnect structure, for example substrate strip 524, would contain multiple device sites; while singulated interposers 528A-F would be individually placed relative to substrate strip 524. In the depicted example, the contact solder bumps are depicted on the surface of the pillars, the upper surface of which forms a contact pad, with the protrusions formed on complementary contact pads on the interposer sites. In other examples, however, the protrusions may be formed on the upper contact pad surface of the pillars, with the solder bumps formed on interposer contact pads.

With either structure, the interconnect structures will be attached to one another in accordance with the techniques described herein. Once the interconnect structures have been attached to one another, the various device sites will be singulated to result in discrete devices, such as microelectronic device 500 depicted in FIG. 5A.

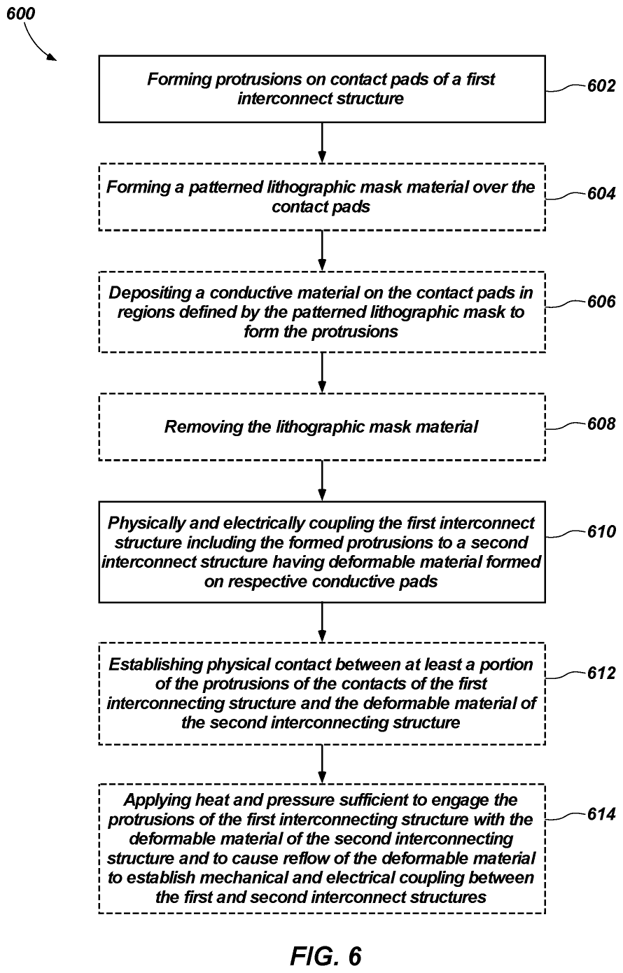

Referring now to FIG. 6, the figure depicts representative operations of an example method 600 for forming a microelectronic device. As indicated at 602, a first operation includes forming protrusions on respective contact pads of a first interconnect structure. Such operation can be performed, for example, through any of the example processes sees discussed above with respect to FIGS. 2A-2B, 3A-3B, and 4A-4B.

For purposes of illustration, optional operations 604, 606, and 608 (depicted within dashed lines) may be implemented to perform operation 602. As indicated at 604, a patterned lithographic mask material may be formed over contact pads on a first interconnect structure. In most cases, the mask material will be formed either as one or more layers of dry resist or as a spin on material. The deposited resist may then be patterned as desired. As indicated at 606, a conductive material may then be deposited on the contact pads in regions defined by the patterned lithographic mask to form the protrusions. This can be performed, for example, as described in reference to FIGS. 4A-4B. Subsequently, as indicated at 608, the lithographic mask material will be removed; leaving the contact pads with the protrusions extending therefrom.

After forming the protrusions of operation 602 (whether or not formed in accordance with example operations 604-608), the first interconnect structure (with the protrusions) will be physically and electrically coupled to a second interconnect structure having deformable material, as indicated at 610. The deformable material will be in locations to be engaged by the protrusions of the first interconnect structure when the two structures are brought into proximity with one another. In some examples, the performing of operation 610 can include optional operations 612, 614 (indicated within dashed lines). As indicated at 612, physical contact between at least a portion of the protrusions of the contacts of the first interconnecting structure and the deformable material of the second interconnecting structure is established. One such initial physical contact is established, heat and pressure may be applied sufficient to engage the protrusions of the first interconnecting structure with the deformable material, and to cause reflow of the deformable material to establish mechanical and electrical coupling between the first and second interconnect substrates. An example process by which this may be performed is thermal compression bonding.

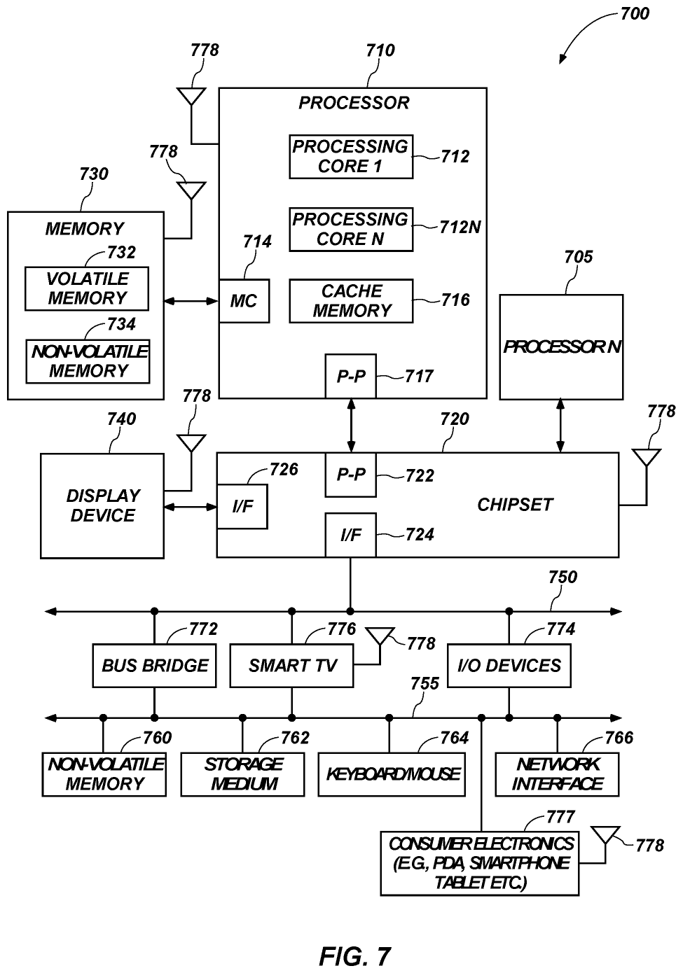

FIG. 7 illustrates a system level diagram, according to one embodiment of the invention. For instance, FIG. 7 depicts an example of an electronic device (e.g., system) including one or more microelectronic devices including one or more interconnects as described herein. FIG. 7 is included to show an example of a higher level device application for the present invention. In one embodiment, system 700 includes, but is not limited to, a desktop computer, a laptop computer, a netbook, a tablet, a notebook computer, a personal digital assistant (PDA), a server, a workstation, a cellular telephone, a mobile computing device, a smart phone, an Internet appliance or any other type of computing device. In some embodiments, system 700 is a system on a chip (SOC) system.

In one embodiment, processor 710 has one or more processing cores 712 and 712N, where 712N represents the Nth processor core inside processor 710 where N is a positive integer. In one embodiment, system 700 includes multiple processors including 710 and 705, where processor 705 has logic similar or identical to the logic of processor 710. In some embodiments, processing core 712 includes, but is not limited to, pre-fetch logic to fetch instructions, decode logic to decode the instructions, execution logic to execute instructions and the like. In some embodiments, processor 710 has a cache memory 716 to cache instructions and/or data for system 700. Cache memory 716 may be organized into a hierarchal structure including one or more levels of cache memory.

In some embodiments, processor 710 includes a memory controller 714, which is operable to perform functions that enable the processor 710 to access and communicate with memory 730 that includes a volatile memory 732 and/or a non-volatile memory 734. In some embodiments, processor 710 is coupled with memory 730 and chipset 720. Processor 710 may also be coupled to a wireless antenna 778 to communicate with any device configured to transmit and/or receive wireless signals. In one embodiment, the wireless antenna interface 778 operates in accordance with, but is not limited to, the IEEE 802.11 standard and its related family, Home Plug AV (HPAV), Ultra Wide Band (UWB), Bluetooth, WiMax, or any form of wireless communication protocol.

In some embodiments, volatile memory 732 includes, but is not limited to, Synchronous Dynamic Random Access Memory (SDRAM), Dynamic Random Access Memory (DRAM), RAMBUS Dynamic Random Access Memory (RDRAM), and/or any other type of random access memory device. Non-volatile memory 734 includes, but is not limited to, flash memory, phase change memory (PCM), read-only memory (ROM), electrically erasable programmable read-only memory (EEPROM), or any other type of non-volatile memory device.

Memory 730 stores information and instructions to be executed by processor 710. In one embodiment, memory 730 may also store temporary variables or other intermediate information while processor 710 is executing instructions. In the illustrated embodiment, chipset 720 connects with processor 710 via Point-to-Point (PtP or P-P) interfaces 717 and 722. Chipset 720 enables processor 710 to connect to other elements in system 700. In some embodiments of the invention, interfaces 717 and 722 operate in accordance with a PtP communication protocol such as the Intel® QuickPath Interconnect (QPI) or the like. In other embodiments, a different interconnect may be used.

In some embodiments, chipset 720 is operable to communicate with processor 710, 705N, display device 740, and other devices 772, 776, 774, 760, 762, 764, 766, 777, etc. Chipset 720 may also be coupled to a wireless antenna 778 to communicate with any device configured to transmit and/or receive wireless signals.

Chipset 720 connects to display device 740 via interface 726. Display 740 may be, for example, a liquid crystal display (LCD), a plasma display, cathode ray tube (CRT) display, or any other form of visual display device. In some embodiments of the invention, processor 710 and chipset 720 are merged into a single SOC. In addition, chipset 720 connects to one or more buses 750 and 755 that interconnect various elements 774, 760, 762, 764, and 766. Buses 750 and 755 may be interconnected together via a bus bridge 772. In one embodiment, chipset 720 couples with a non-volatile memory 760, a mass storage device(s) 762, a keyboard/mouse 764, a network interface 766, a smart TV 776, consumer electronic(s) 777, etc. via interface 724.

In one embodiment, mass storage device 762 includes, but is not limited to, a solid state drive, a hard disk drive, a universal serial bus flash memory drive, or any other form of computer data storage medium. In one embodiment, network interface 766 is implemented by any type of well-known network interface standard including, but not limited to, an Ethernet interface, a universal serial bus (USB) interface, a Peripheral Component Interconnect (PCI) Express interface, a wireless interface and/or any other suitable type of interface. In one embodiment, the wireless interface operates in accordance with, but is not limited to, the IEEE 802.11 standard and its related family, Home Plug AV (HPAV), Ultra Wide Band (UWB), Bluetooth, WiMax, or any form of wireless communication protocol.

While the modules shown in FIG. 7 are depicted as separate blocks within the system 700, the functions performed by some of these blocks may be integrated within a single semiconductor circuit or may be implemented using two or more separate integrated circuits. For example, although cache memory 716 is depicted as a separate block within processor 710, cache memory 716 (or selected aspects of 716) can be incorporated into processor core 712.

To better illustrate the methods and apparatuses described herein, a non-limiting set of Example embodiments are set forth below as numerically identified Examples.

Example 1 is a microelectronic device, comprising: a first interconnect structure comprising first multiple contact structures on a first surface; a second interconnect structure comprising a second multiple contact structures on a second surface in positions to be coupled to respective first multiple contact structures, the second multiple contact structures each having, a respective first portion with a first lateral dimension proximate a dielectric structure of the second interconnect structure, and a protrusion extending from the respective first portion in a direction toward the first interconnect structure, the protrusion having a second portion with a second lateral dimension less than the first lateral dimension of the first portion of the contact structure; and a deformable material establishing electrical and mechanical contact between the first multiple contact structures of the first interconnect structure and respective second multiple contact structures of the second interconnect structure.

In Example 2, the subject matter of Example 1 wherein a first plurality of the second multiple contact structures each include a bond pad having a planar contact surface forming the first portion, and wherein the protrusion extends relative to the planar contact surface.

In Example 3, the subject matter of any one or more of Examples 1-2 wherein the first multiple contact structures comprise: a first plurality of contact structures, each of a first lateral dimension; and a second plurality of contact structures, each of a second lateral dimension, smaller than the first lateral dimension.

In Example 4, the subject matter of any one or more of Examples 1-3 optionally include protrusions each extending between 3 μm and 10 μm above the respective first portion of the second multiple contact structures.

In Example 5, the subject matter of any one or more of Examples 1-4 wherein the deformable material comprises solder.

In Example 6, the subject matter of any one or more of Examples 1-5 wherein the deformable material comprises a conductive adhesive.

In Example 7, the subject matter of any one or more of Examples 1-6 wherein the first interconnect structure comprises a semiconductor die.

In Example 8, the subject matter of any one or more of Examples 1-7 wherein the second interconnect structure comprises an interposer, a redistribution layer, or a spacer.

In Example 9, the subject matter of any one or more of Examples 1-8 wherein at least a portion of the second multiple contact structures each include multiple protrusions extending toward the first interconnect structure.

Example 10 is a method of forming a microelectronic device, comprising: engaging a first interconnect structure having deformable material formed on respective conductive pads with a second interconnect structure having multiple contacts configured to couple to the deformable material of the first interconnect structure; wherein the multiple contacts of the second interconnect structure each include a respective first contact surface and a protrusion extending outwardly from the first contact surface in the direction of the first interconnect structure; and wherein engaging the first interconnect structure with the second interconnect structure comprises establishing physical contact between at least a portion of the protrusions of the contacts of the second interconnect structure and the deformable material of the first interconnect structure.

In Example 11, the subject matter of Example 10 optionally includes securing the first interconnect structure to the second interconnect structure through thermal compression bonding.

In Example 12, the subject matter of Example 11 wherein the deformable material comprises solder bumps formed on the first interconnect structure conductive pads.

In Example 13, the subject matter of any one or more of Examples 11-12 wherein the deformable material comprises conductive adhesive formed on the first interconnect structure conductive pads.

In Example 14, the subject matter of any one or more of Examples 10-13 wherein a first plurality of the multiple contacts of the second interconnect structure each include a planar contact surface forming the respective first contact surface.

In Example 15, the subject matter of any one or more of Examples 10-14 optionally includes securing the first interconnect structure to the second interconnect structure, including reflowing the deformable bumps.

In Example 16, the subject matter of any one or more of Examples 10-15 wherein the first interconnect structure comprises a semiconductor die.

In Example 17, the subject matter of any one or more of Examples 10-16 wherein the second interconnect structure comprises at least one of an interposer, a redistribution layer, and a spacer.

In Example 18, the subject matter of any one or more of Examples 10-17 wherein at the time of engaging the first interconnect structure with the second interconnect structure, at least one of the first and second interconnect structures forms a portion of a wafer containing multiple interconnect structure sites.

In Example 19, the subject matter of any one or more of Examples 15-18 wherein at the time of engaging the first interconnect structure with the second interconnect structure, at least one of the first and second interconnect structures forms a portion of a wafer strip containing multiple interconnect structure sites; and further comprising, after securing the first interconnect structure to the second interconnect structure, singulating one of the first and second interconnect structures from other interconnect structures on the portion of the wafer.

Example 20 is a method of forming a microelectronic device, comprising: forming a protrusion on a contact pad of an interconnect structure, wherein the contact pad has a first horizontal dimension, and wherein the protrusion has a second maximum horizontal dimension of up to 30% of the first horizontal dimension, comprising, forming a patterned lithographic mask material over the contact pad, the patterned lithographic mask material defining a form for the protrusion, depositing a conductive material on the contact pad in regions defined by the patterned lithographic mask to form the protrusion, and removing the lithographic mask material.

In Example 21, the subject matter of Example 20 wherein depositing the conductive material is performed through electrodeposition.

In Example 22, the subject matter of Example 21 wherein the electrodeposition comprises reverse current electrodeposition.

In Example 23, the subject matter of any one or more of Examples 21-22 wherein the electrodeposition comprises direct current electrodeposition.

In Example 24, the subject matter of any one or more of Examples 20-23 wherein the protrusion is formed to have a non-uniform horizontal cross-section along its height.

In Example 25, the subject matter of any one or more of Examples 20-24 wherein the protrusion includes a tapered profile in at least an upper portion of the protrusion.

In Example 26, the subject matter of any one or more of Examples 20-25 wherein the conductive material comprises at least one of copper, nickel, cobalt, iron, gold, silver, tin, and palladium.

Example 27 is an electronic system, comprising: A microelectronic device, comprising: a first interconnect structure comprising first multiple contact structures on a first surface; a second interconnect structure comprising a second multiple contact structures on a first surface in positions to be coupled to respective first multiple contact structures, the second multiple contact structures each having, a respective first portion with a first lateral dimension proximate a dielectric structure of the second interconnect structure, and a protrusion extending in a direction toward the first interconnect structure, the protrusion having a second portion with a second lateral dimension less than the first lateral dimension of the first portion of the contact structure; and a deformable material establishing electrical and mechanical contact between the first multiple contact structures the first interconnect structure and respective second multiple contact structures of the second interconnect structure; and wherein at least one of the first and second interconnect structures comprises a processor; and at least one of an additional semiconductor device, a mass storage device and a network interface operably coupled to the microelectronic device.

In Example 28, the subject matter of Example 27 wherein a first plurality of the second multiple contact structures each include a bond pad having a planar contact surface forming the first portion, and wherein the protrusion extends relative to the planar contact surface.

In Example 29, the subject matter of any one or more of Examples 27-28 wherein the protrusion includes a generally tapered profile in at least an upper portion of the protrusion.

In Example 30, the subject matter of any one or more of Examples 1-9 are formed in accordance with the methods of any one or more of Examples 10-26.

In Example 31, the subject matter of any one or more of Examples 27-29, are formed in accordance with the methods of any one or more of Examples 10-26.

In Example 32, the subject matter of any one or more of Examples 27-29 optionally includes the structure of any one or more of Examples 1-9.

The above detailed description includes references to the accompanying drawings, which form a part of the detailed description. The drawings show, by way of illustration, specific embodiments in which the invention can be practiced. These embodiments are also referred to herein as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “where.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. § 1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

1. A microelectronic device, comprising:
a first interconnect structure comprising first multiple contact structures on a first surface;
a second interconnect structure comprising second multiple contact structures on a second surface in positions to be coupled to respective first multiple contact structures, the second multiple contact structures each having,
a respective first portion with a first lateral dimension proximate a dielectric structure of the second interconnect structure, and
a protrusion extending from the respective first portion in a direction toward the first interconnect structure, the protrusion having a second portion with a second lateral dimension less than the first lateral dimension of the first portion of the contact structure; and
a deformable material establishing electrical and mechanical contact between the first multiple contact structures of the first interconnect structure and respective second multiple contact structures of the second interconnect structure.

2. The microelectronic device of claim 1, wherein a first plurality of the second multiple contact structures each include a bond pad having a planar contact surface forming the first portion, and wherein the protrusion extends relative to the planar contact surface.

3. The microelectronic device of claim 1, wherein the first multiple contact structures comprise:
a first plurality of contact structures, each of a first lateral dimension; and
a second plurality of contact structures, each of a second lateral dimension, smaller than the first lateral dimension.

4. The microelectronic device of claim 1, wherein the protrusions each extend between 3 μm and 10 μm above the respective first portion of the second multiple contact structures.

5. The microelectronic device of claim 1, wherein the deformable material comprises solder.

6. The microelectronic device of claim 1, wherein the deformable material comprises a conductive adhesive.

7. The microelectronic device of claim 1, wherein the first interconnect structure comprises a semiconductor die.

8. The microelectronic device of claim 1, wherein the second interconnect structure comprises an interposer, a redistribution layer, or a spacer.

9. The microelectronic device of claim 1, wherein at least a portion of the second multiple contact structures each include multiple protrusions extending toward the first interconnect structure.

10. A method of forming a microelectronic device, comprising:
engaging a first interconnect structure having deformable material formed on respective conductive pads with a second interconnect structure having multiple contacts configured to couple to the deformable material of the first interconnect structure;
wherein the multiple contacts of the second interconnect structure each include a respective first contact surface and a protrusion extending outwardly from the first contact surface in the direction of the first interconnect structure; and
wherein engaging the first interconnect structure with the second interconnect structure comprises establishing physical contact between at least a portion of the protrusions of the contacts of the second interconnect structure and the deformable material of the first interconnect structure.

11. The method of claim 10, further comprising securing the first interconnect structure to the second interconnect structure through thermal compression bonding.

12. The method of claim 11, wherein the deformable material comprises solder bumps formed on the first interconnect structure conductive pads.

13. The method of claim 11, wherein the deformable material comprises conductive adhesive formed on the first interconnect structure conductive pads.

14. The method of claim 10, wherein a first plurality of the multiple contacts of the second interconnect structure each include a planar contact surface forming the respective first contact surface.

15. The method of claim 10, further comprising securing the first interconnect structure to the second interconnect structure, including reflowing the deformable bumps.

16. The method of claim 10, wherein the first interconnect structure comprises a semiconductor die.

17. The method of claim 10, wherein the second interconnect structure comprises at least one of an interposer, a redistribution layer, and a spacer.

18. The method of claim 10, wherein at the time of engaging the first interconnect structure with the second interconnect structure, at least one of the first and second interconnect structures forms a portion of a wafer containing multiple interconnect structure sites.

19. The method of claim 15, wherein at the time of engaging the first interconnect structure with the second interconnect structure, at least one of the first and second interconnect structures forms a portion of a wafer containing multiple interconnect structure sites; and
further comprising, after securing the first interconnect structure to the second interconnect structure, singulating one of the first and second interconnect structures from other interconnect structures on the portion of a wafer.

20. An electronic system, comprising:
a microelectronic device, comprising:
a first interconnect structure comprising first multiple contact structures on a first surface;
a second interconnect structure comprising second multiple contact structures on a second surface in positions to be coupled to respective first multiple contact structures, the second multiple contact structures each having,
a respective first portion with a first lateral dimension proximate a dielectric structure of the second interconnect structure, and
a protrusion extending in a direction toward the first interconnect structure, the protrusion having a second portion with a second lateral dimension less than the first lateral dimension of the first portion of the contact structure; and
a deformable material establishing electrical and mechanical contact between the first multiple contact structures the first interconnect structure and respective second multiple contact structures of the second interconnect structure; and
wherein at least one of the first and second interconnect structures comprises a processor; and
at least one of an additional semiconductor device, a mass storage device, and a network interface operably coupled to the microelectronic device.

21. The system of claim 20, wherein a first plurality of the second multiple contact structures each include a bond pad having a planar contact surface forming the first portion, and wherein the protrusion extends relative to the planar contact surface.

22. The system of claim 20, wherein the protrusion includes a generally tapered profile in at least an upper portion of the protrusion.
